(19) United States
(12) Patent Application Publication
(10) Pub. No.: US 2007/0080404 A1
(43) Pub. Date: Apr. 12, 2007

(54) SEMICONDUCTOR DEVICE

(75) Inventors: Taketo FUKURO, Chiba (JP); Masao OKIHARA, Miyagi (JP)

Correspondence Address: GLOBAL IP COUNSELORS, LLP, 1233 20TH STREET, NW, SUITE 700, WASHINGTON, DC, 20036-2680, US

(73) Assignee: OKI ELECTRIC INDUSTRY CO., LTD., Tokyo (JP)

(21) Appl. No.: 11/533,370

(22) Filed: Sep. 20, 2006

(30) Foreign Application Priority Data
Oct. 7, 2005 (JP) 2005-294243

(51) Int. Cl. H01L 23/62

(52) U.S. Cl. 257/360

(57) ABSTRACT

A semiconductor device includes a substrate, a first oxide film lying on the substrate, a thin semiconductor film lying on the first oxide film, a first terminal formed on the semiconductor film, a second terminal formed on the semiconductor film, a semiconductor element formed on the semiconductor film and electrically connected between the first and second terminals, and a protective diode formed on the semiconductor film and electrically connected in between the second and first terminal in a forward direction.

### BACKGROUND OF THE INVENTION

1. Field of the Invention

The present invention relates to a semiconductor device which in particular uses an SOI substrate and is capable of preventing possible damage which could occur in a manufacturing process thereof, and to a method of manufacturing the same.

2. Background Information

Conventionally, a semiconductor device using a bulk substrate usually has a protective diode connected between an input terminal of a circuit and the substrate in a forward direction, for the purpose of preventing a semiconductor element from being damaged by possible plasma current occurring in a process of manufacturing the semiconductor device. A circuit structure of a semiconductor device 90 having such conventional structure is shown in FIG. 1. In the following description, a case in which the semiconductor device 90 has an inverter 91 built inside a bulk substrate will be shown.

As shown in FIG. 1, the conventional semiconductor device 90 has a p type MOS (metal oxide semiconductor) transistor (hereinafter to be referred to as PMOS) P91 and an n type MOS transistor (hereinafter to be referred to as NMOS) N91 connected in between a power supply line Vdd and a power supply line Vss in series. A source of the PMOS transistor P91 is connected to the power supply line Vdd. A source of the NMOS transistor N91 is connected to the power supply line Vss. Drains of the PMOS transistor P91 and the NMOS transistor N91 are connected mutually and are also connected to an output terminal OUT. Gates of the PMOS transistor P91 and the NMOS transistor N91 are connected mutually and are also connected to an input terminal IN. The input terminal IN is connected to an upper layer metal wiring 93 in the semiconductor device 90 and also to the bulk substrate through a protective diode 92 being connected in a forward direction.

In this way, in the conventional art, the protective diode (92) is connected only in between the input terminal (IN) and the bulk substrate.

In the meantime, in recent years, for the purpose of miniaturizing and speeding up the operation of a semiconductor device, a semiconductor substrate having an SOI (silicon on insulator) structure has come to be used instead of a bulk substrate.

As a reference, Japanese Patent No. 3415401 (patent reference 1) discloses a structure in which a protective diode is disposed in between an input terminal and a power supply voltage Vss or Vdd, for the purpose of improving the resistance against a possible surge current that might occur during operation of a semiconductor device built inside an SOI substrate.

In the conventional semiconductor device formed in the bulk substrate, as described above, the potentials of the source, drain and gate are kept at the same potential as that of the bulk substrate during the manufacturing process. Here, the gate is kept at the same potential as the bulk substrate because of the connection thereof to the bulk substrate via the protective diode.

On the other hand, in the semiconductor device using an SOI substrate, unlike the semiconductor device formed in the bulk substrate, the source, drain and gate are in an electrically floating state with respect to the SOI substrate. This is because an insulation layer exists between a silicon film, which is a region where a semiconductor element is formed, and the substrate. In this semiconductor device using an SOI substrate, if a protective diode is arranged in between the gate and the substrate as in the case of the semiconductor device using the bulk substrate, the gate will have a different potential from that of the source and drain. Therefore, possible plasma current that could occur during the manufacturing process can flow intensively to the gate, and as a result, the semiconductor element might be damaged.

Likewise, with respect to the structure disclosed in patent reference 1, since it has the protective diode arranged in between the input terminal and the power supply voltage Vss or Vdd, it is not possible to resolve the problem in which the semiconductor element might be damaged due to plasma current, as mentioned above. Moreover, a protective transistor disclosed in patent reference 1 has a conductive layer on a region where n or p type impurities are diffused. If, for instance, a full depletion type SOI substrate is used in a structure in which there is a conductive layer on an impurity diffused region, depletion areas might be generated in the impurity diffused region, and thereby, a withstand voltage of the diode, i.e., the voltage at the time of break-down, will become high. Accordingly, it will be difficult to effectively discharge a surge current such as plasma current, and thereby, protective performance of the protective transistor might deteriorate. Furthermore, as the withstand voltage of the diode gets high, there are more possibilities that the semiconductor device will have less control over plasma damage.

In view of the above, it will be apparent to those skilled in the art from this disclosure that there exists a need for an improved semiconductor device and an improved method of manufacturing the semiconductor device. This invention addresses this need in the art as well as other needs, which will become apparent to those skilled in the art from this disclosure.

### SUMMARY OF THE INVENTION

It is therefore an object of the present invention to resolve the above-described problems, and to provide a semiconductor device which is capable of preventing itself from being damaged by plasma current that might occur during a manufacturing process thereof and capable of preventing a withstand voltage of a diode from becoming higher, and a method of manufacturing such semiconductor device.

In accordance with a first aspect of the present invention, a semiconductor device comprises a substrate, a first oxide film lying on the substrate, a thin semiconductor film lying on the first oxide film, a first terminal formed on the semiconductor film, a second terminal formed on the semiconductor film, a semiconductor element formed on the semiconductor film and electrically connected between the first and second terminals, and a protective diode formed on the semiconductor film and electrically connected in between the second and first terminal in a forward direction.

In accordance with a second aspect of the present invention, a method of manufacturing a semiconductor device comprises the steps of: preparing an SOI substrate having a substrate, an oxide film lying on the substrate and a thin semiconductor film lying on the oxide film; zoning the semiconductor film into first and second element formation regions; forming a protective diode in the first element formation region, the protective diode having a first region with p type conductivity and a second region with n type conductivity; forming a transistor in the second element formation region, the transistor having a gate insulation film, a gate electrode and a pair of doped regions; forming a first wiring which is electrically connected between the first region of the protective diode and the doped region of the transistor; and forming a second wiring which is electrically connected between the second region of the protective diode and the gate electrode of the transistor.

These and other objects, features, aspects, and advantages of the present invention will become apparent to those skilled in the art from the following detailed description, which, taken in conjunction with the annexed drawings, discloses preferred embodiments of the present invention.

### BRIEF DESCRIPTION OF THE DRAWINGS

Referring now to the attached drawings which form a part of this original disclosure:

FIG. 1 is a circuit diagram showing the structure of a conventional semiconductor device;

FIG. 2 is a circuit diagram showing the structure of a semiconductor device according to a first embodiment of the present invention;

FIG. 3 is a sectional view showing the layer structure of the semiconductor device according to the first embodiment of the present invention;

FIG. 4A-4C, 5A-5C, 6A-6B, 7A-7B, 8A-8B, and FIG. 9 are process diagrams showing manufacturing processes in the method of manufacturing the semiconductor device according to the first embodiment of the present invention;

FIG. 10 is a circuit diagram showing the structure of a semiconductor device according to a second embodiment of the present invention;

FIG. 11 is a sectional view showing the layer structure of the semiconductor device according to the second embodiment of the present invention; and

FIG. 12A-12C, 13A-13C, 14A-14B, 15A-15B, 16A-16B, 17A-17B, and FIG. 18 are process diagrams showing manufacturing processes in the method of manufacturing the semiconductor device according to the second embodiment of the present invention.

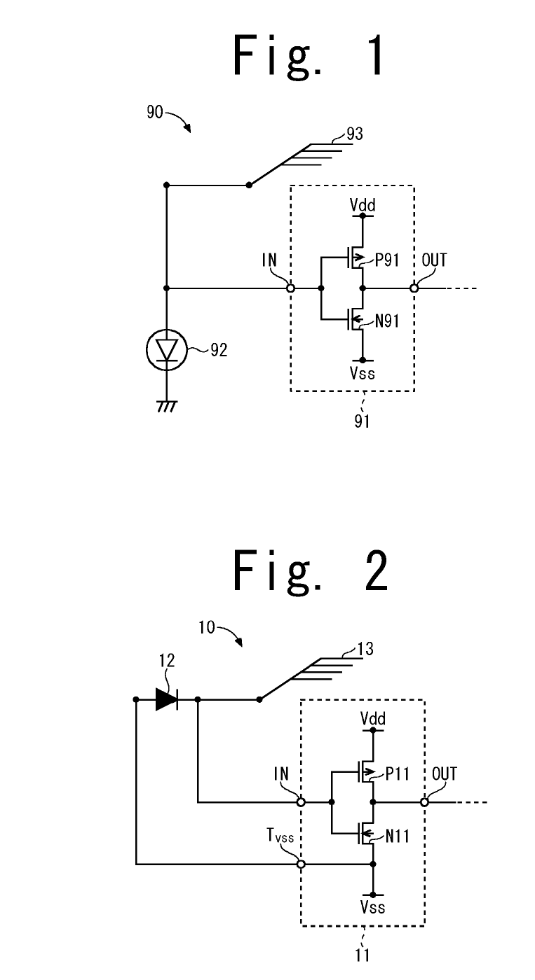

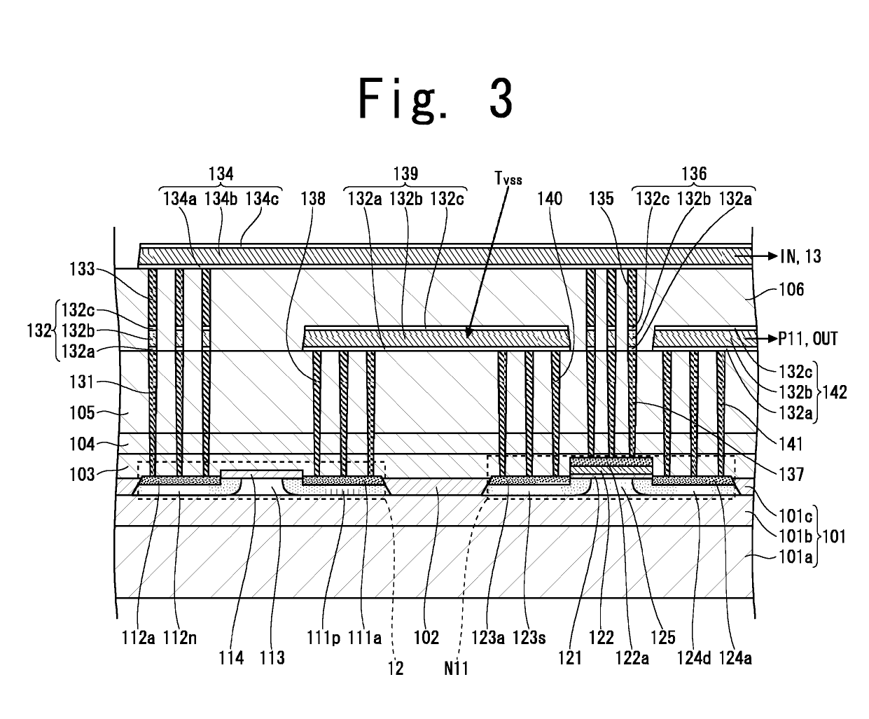

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

In the following, the structure shown in each drawing is shown in a certain shape, size and position in a way simple enough to show the outline of the present invention. Therefore, the shape, size and position of the semiconductor device according to the present invention are not limited to the ones shown in the drawings. In addition, in each drawing, in order to clearly show the structure, a portion of the hatching in the cross-sectional surface is omitted. Moreover, numerical values indicated in the following description are only given as examples, and therefore, they are not in the nature of limiting the present invention.

### First Embodiment

First, a first embodiment of the present invention will be described in detail with reference to the drawings. In this embodiment, a case in which a semiconductor element to be formed in an SOI substrate as an inverter will be described.

Structure

FIG. 2 is a circuit diagram showing the structure of a semiconductor device 10 according to the first embodiment of the present invention. As shown in FIG. 2, the semiconductor device 10 has a structure in which a PMOS transistor P11 and an NMOS transistor N11 are connected in series in between a power supply line Vdd and a power supply line Vss. Drains of the PMOS transistor P11 and the NMOS transistor N11 are connected mutually and are also connected to an output terminal OUT. A source of the PMOS transistor P11 is connected to the power supply line Vdd. A source of the NMOS transistor N11 is connected to the power supply line Vss and also to a Vss terminal Tvss (i.e., a second terminal). Gates of the PMOS transistor P11 and the NMOS transistor N11 are connected mutually and are also connected to an input terminal IN (i.e., a first terminal).

The semiconductor device 10 has a protective diode 12. An anode of the protective diode 12 is connected to a Vss terminal Tvss. A cathode of the protective diode 12 is connected to the input terminal IN and also to a metal wiring 13. Accordingly, in this embodiment, the protective diode 12 is disposed in between a source and a gate of an inverter 11, serving as a semiconductor element, in a forward direction. The metal wiring 13 is connected to a support substrate (corresponding to a silicon substrate 101a which will be mentioned later on) in the SOI substrate via a wiring (not shown). By having such structure, it is possible to prevent electrical charge that could charge the source of the NMOS transistor N11 from flowing from the metal wiring 13 or the input terminal IN to the source of the NMOS transistor N11, and thus it is possible to maintain the potentials of the source and gate of the inverter 11 at the same potential. As a result, it will become possible to prevent the semiconductor element formed in the SOI substrate from being damaged by plasma current. In the meantime, the cathode of the protective diode 12 and the gate of the inverter 11 are electrically connected to the metal wiring 13 (i.e., a metal layer) which serves as a signal line.

Sectional Structure of Semiconductor Device

Now, the layer structure of the semiconductor device 10 according to the first embodiment of the present invention will be described in detail with reference to a drawing. FIG. 3 is a sectional view showing the layer structure of the semiconductor device 10. In FIG. 3, a section of the semiconductor device 10 cut along a surface perpendicular to the upper surface of the SOI substrate 101 is shown. Moreover, in FIG. 3, for the convenience of explanation, the structure of the PMOS transistor P11 is omitted.

As shown in FIG. 3, the protective diode 12 and the NMOS transistor N11 are formed in a silicon film 101c of the SOI substrate 101 having a structure in which an oxide film 101b and the silicon film 101c are laminated sequentially on a silicon substrate 101a (i.e., the support substrate). Here, the oxide film 101b may be a buried oxide film (i.e., a BOX film). The protective diode 12 and the NMOS transistor N11 are electrically separated by an element separating insulation film 102 which functions to zone element formation regions in the SOI substrate 101. This structure is the same with respect to the PMOS transistor P11 as well.

Sectional Structure of Protective Diode

The protective diode 12 has a diffusion region 111p having p type conductivity (hereinafter to be referred to as a P diffusion region 111p), a silicide film 111a formed on the upper part of the P diffusion region 111p (i.e., first diffusion region or first region), a diffusion region 112n having n type conductivity (hereinafter to be referred to as an N diffusion region 112n), a silicide film 112a formed on the upper part of the N diffusion region 112n (i.e., second diffusion region or second region), and a low diffusion region 113 (i.e., third diffusion region) having p or n type conductivity. In this way, the protective diode 12 in this embodiment has a lateral structure with respect to the SOI substrate 101. That is, in this embodiment, a lateral type diode is used as the protective diode 12.

In the above structure, the P diffusion region 111p is formed by having p type impurity ions (e.g., boron fluoride BF₂) implanted into a predetermined region of the silicon film 101c to a dose amount of about 1×10¹⁵/cm², for instance. The upper part of this P diffusion region 111p is made to have low resistance by having the silicide film 111a formed thereon as mentioned above.

The N diffusion region 112n is formed by having n type impurity ions (e.g., phosphorous P) implanted into a predetermined region of the silicon film 101c to a dose amount of about 1×10¹⁵/cm², for instance. As with the P diffusion region 111p, the upper part of this N diffusion region 112n is also made to have low resistance by having the silicide film 112a formed thereon as mentioned above.

As mentioned above, the low diffusion region 113 having p or n type conductivity is formed in between the P diffusion region 111p and the N diffusion region 112n. In this embodiment, the low diffusion region 113 will be considered as having p type conductivity. Impurity density of the low diffusion region 113 may be the same as the substrate density provided that the SOI substrate is formed using a p type silicon substrate, for instance. Here, the substrate resistance of the silicon substrate is to be about 8 to 22 Ω (ohm), for instance.

The protective diode 12 has a protective film 114 formed on a surface extending from a portion of the upper surface of the P diffusion region 111p to a portion of the upper surface of the N diffusion region 112n via the upper surface of the low diffusion region 113. This protective film 114 serves as a protective film against silicification at the time of forming the silicide films 111a, 112a and 122a. For instance, the protective film 114 may be a silicon oxide film, and it may be about 400 Å (angstrom) thick.

Sectional Structure of NMOS Transistor

The NMOS transistor N11 has a gate insulation film 121 formed on the silicon film 101c, a gate electrode 122 formed on the gate insulation film 121, a silicide film 122a formed on the upper part of the gate electrode 122, a pair of source 123s and drain 124d (i.e., a pair of diffusion regions) having n type conductivity, silicide films 123a and 124a formed on the upper parts of the source 123s and drain 124d, respectively, and a well region 125 having p type conductivity.

In the above structure, the gate insulation film 121 may be a silicon oxide film, and it may be about 400 Å thick, for instance. Here, the thickness of the gate insulation film 121 should preferably be the same as the thickness of the protective film 114 described above. Thereby, it will be possible to form the protective film 114 and the gate insulation film 121 in the same process.

The gate electrode 122 may be a conductive poly-silicon film including predetermined impurities, and it may be about 2000 Å thick, for instance.

The source 123s and drain 124d are diffusion regions formed on a pair of regions in the silicon film 101c which sandwich a region underneath the gate electrode 122. For instance, the source 123s and drain 124d may be formed by having n type impurities (e.g., phosphorous P) implanted in a self-aligning manner into the silicon film 101c to a dose amount of about 1×10¹⁵/cm², for instance, while using the gate electrode 122 as a mask. The upper parts of the source 123s and drain 124d are made to have low resistance by having the silicide films 123a and 124a formed thereon, respectively.

The well region 125 formed in between the source 123s and drain 124d is formed by having p type impurities (e.g., boron B) implanted into the silicon film 101c to a dose amount of about 1×10¹²/cm², for instance. The well region 125 is a region where a depletion layer is to be formed and current will flow thereto at the time of operation.

On the SOI substrate where the protective diode 12 and the NMOS transistor N11 are formed in the above-described way, a first passivation 103, a second passivation 104, and a first interlayer insulation film 105 are formed. By these layers, the protective diode 12 and the NMOS transistor N11 are electrically separated from the semiconductor element, wires, etc., in the upper layer.

The first passivation 103 may be a silicon oxide film, and may be about 700 Å thick, for instance. The second passivation 104 may be a silicon oxide film, and may be about 1000 Å thick, for instance. The first interlayer insulation film 105 may be a silicon oxide film, and may be about 8000 Å thick, for instance. On the first interlayer insulation film 105, a second interlayer insulation film 106 is formed. This second interlayer insulation film 106 may be a silicon oxide film, and may be about 8000 Å thick, for instance.

The N diffusion region 112n in the protective diode 12 is electrically connected to a second upper layer wiring 134, which is formed on the second interlayer insulation film 106, via contact plugs 131 formed so as to penetrate through the first passivation 103, the second passivation 104 and the first interlayer insulation film 105, first upper layer wirings 132 formed on the first interlayer insulation film 105, and contact plugs 133 formed so as to penetrate through the second interlayer insulation film 106. Likewise, the gate electrode 122 in the NMOS transistor N11 is electrically connected to the second upper layer wiring 134, which is formed on the second interlayer insulation film 106, via contact plugs 137 formed so as to penetrate through the first passivation 103, the second passivation 104 and the first interlayer insulation film 105, first upper layer wirings 136 formed on the first interlayer insulation film 105, and contact plugs 135 formed so as to penetrate through the second interlayer insulation film 106.

By such structure, the N diffusion region 112n of the protective diode 12 and the gate electrode 122 of the NMOS transistor N11 are connected electrically. Here, the second upper layer wiring 134 is connected to the input terminal IN and the metal wiring 13 shown in FIG. 2. Moreover, the contact plugs 131, the first upper layer wirings 132, the contact plugs 133, the second upper layer wiring 134, the contact plugs 135, the first upper layer wirings 136, and the contact plugs 137 are second wirings which connect between the N diffusion region 112n of the protective diode 12 and the gate of the NMOS transistor N11.

The P diffusion region 111p in the protective diode 12 is electrically connected to a first upper layer wiring 139, which is formed on the first interlayer insulation film 105, via contact plugs 138 formed so as to penetrate through the first passivation 103, the second passivation 104 and the first interlayer insulation film 105. Likewise, the source 123s in the NMOS transistor N11 is electrically connected to the first upper layer wiring 139, which is formed on the first interlayer insulation film 105, via contact plugs 140 formed so as to penetrate through the first passivation 103, the second passivation 104 and the first interlayer insulation film 105.

By such structure, the P diffusion region 111p of the protective diode 12 and the source 123s of the NMOS transistor N11 are connected electrically. Here, the first upper layer wiring 139 includes the Vss terminal Tvss shown in FIG. 2. Moreover, the contact plugs 138, the first upper layer wiring 139 and the contact plugs 140 are first wirings which connect between the P diffusion region 111p of the protective diode 12 and the source of the NMOS transistor N11.

The drain 124d in the NMOS transistor N11 is electrically connected to a first upper layer wiring 142, which is formed on the first interlayer insulation film 105, via contact plugs 141 formed so as to penetrate through the first passivation 103, the second passivation 104 and the first interlayer insulation film 105. The first upper layer wiring 142 is connected to a drain and an output terminal OUT of the PMOS transistor P11 (not shown).

By such structure, the drain 124d of the NMOS transistor N11 is electrically connected to the drain and the output terminal OUT of the PMOS transistor P11.

The contact plugs 131, 137, 138, 140 and 141 may be formed by filling contact holes formed in the first passivation 103, the second passivation 104 and the first interlayer insulation film 105 with conductive material such as tungsten (W), for instance. In the meantime, the contact plugs 133 and 135 may be formed by filling contact holes formed in the second interlayer insulation film 106 with conductive material such as tungsten (W), for instance.

The first upper layer wirings 132, 136, 139 and 142 may be formed by laminating a lamination film 132a, an alloy film 132b and a lamination film 132c sequentially on the first interlayer insulation film 105, and then patterning this laminated body. Here, the lamination film 132a includes a titanium (Ti) film about 300 Å thick and a titanium nitride (TiN) film about 200 Å thick, for instance, the alloy film 132b is a film about 5000 Å thick made of aluminum (Al) and copper (Cu), for instance, and the lamination film 132c includes a titanium (Ti) film about 300 Å thick and a titanium nitride (TiN) film about 200 Å thick, for instance.

Likewise, the second upper layer wiring 134 may be formed by laminating a lamination film 134a, an alloy film 134b and a lamination film 134c sequentially on the second interlayer insulation film 106, and then patterning this laminated body. Here, the lamination film 134a includes a titanium (Ti) film about 300 Å thick and a titanium nitride (TiN) film about 200 Å thick, for instance, the alloy film 134b is a film about 5000 Å thick made of aluminum (Al) and copper (Cu), for instance, and the lamination film 134c includes a titanium (Ti) film about 300 Å thick and a titanium nitride (TiN) film about 200 Å thick, for instance. Method of Manufacturing the Semiconductor Device

Now, a method of manufacturing the semiconductor device 10 according to the first embodiment of the present invention will be described in detail with reference to the drawings. The following description will be based on a sectional structure of the semiconductor device 10 as shown in FIG. 3, the semiconductor device 10 being cut along a surface perpendicular to the upper surface of the SOI substrate 101. Moreover, in the following, the manufacturing method will be described focusing on the protective diode 12 and the NMOS transistor N11.

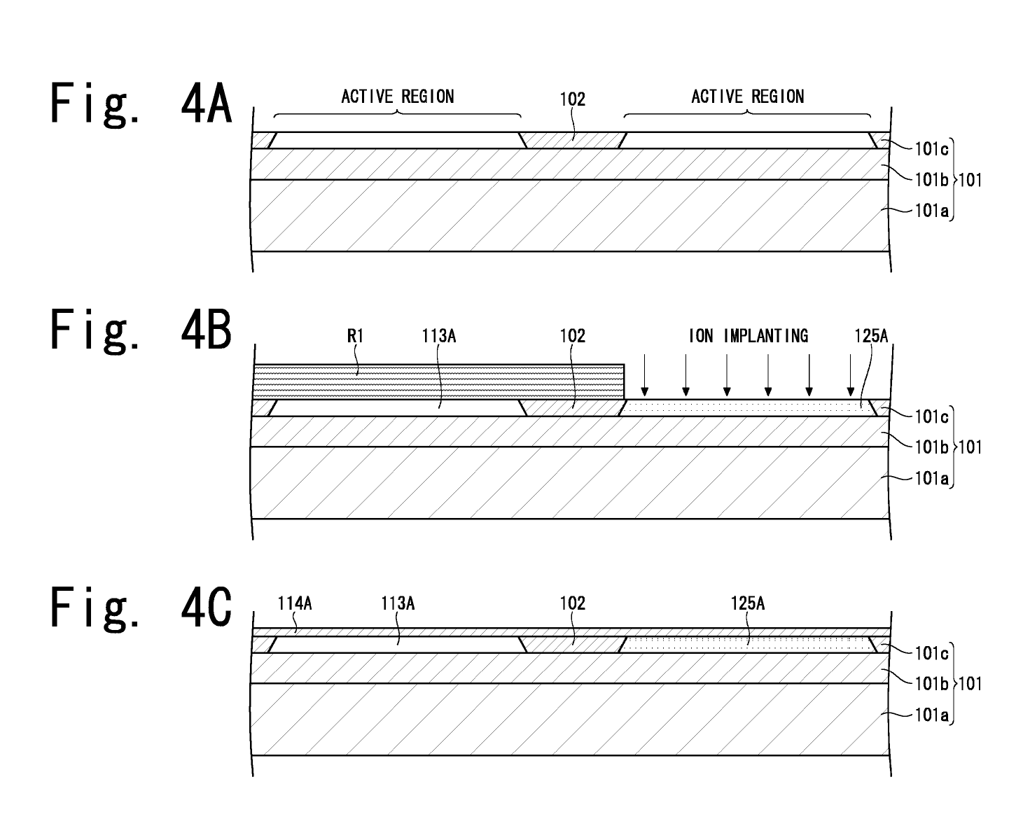

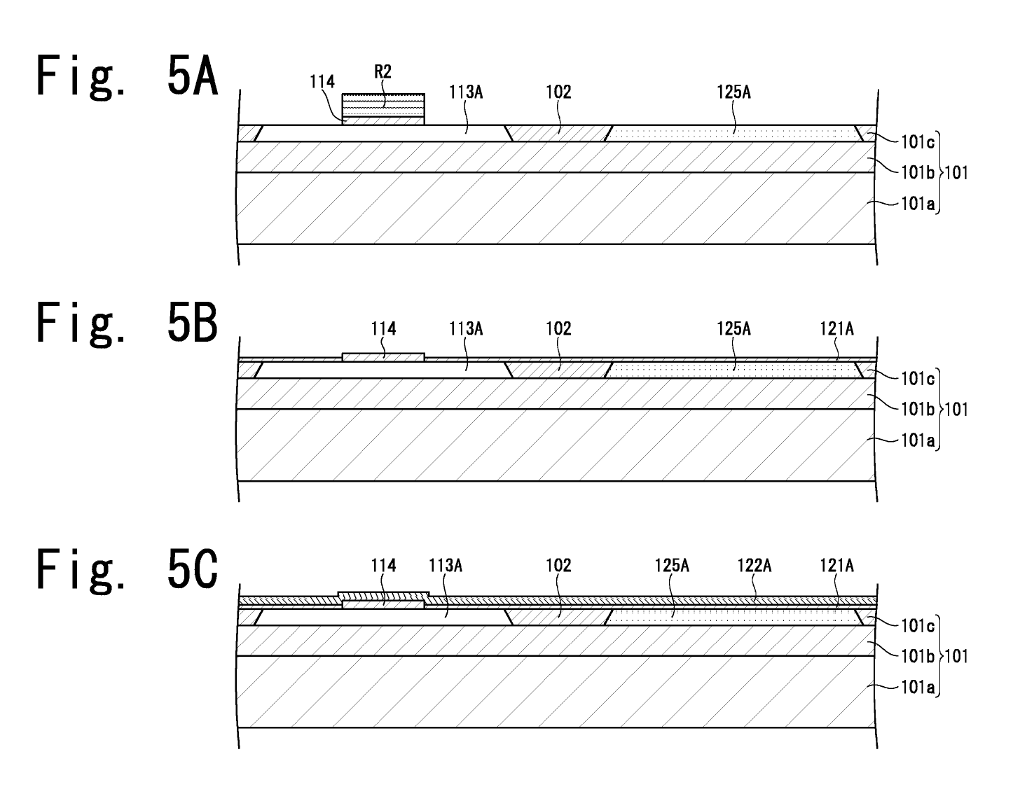

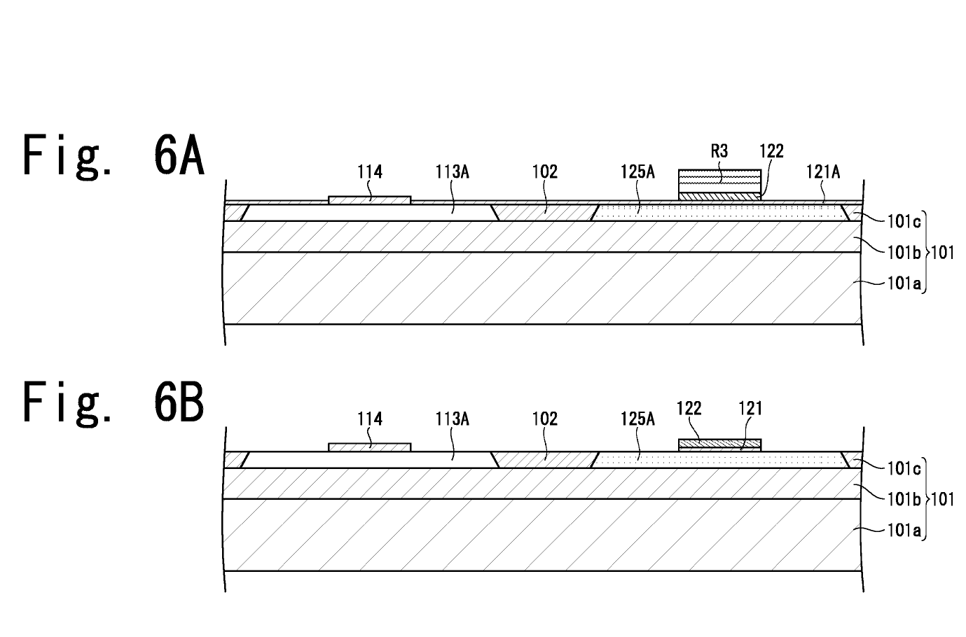

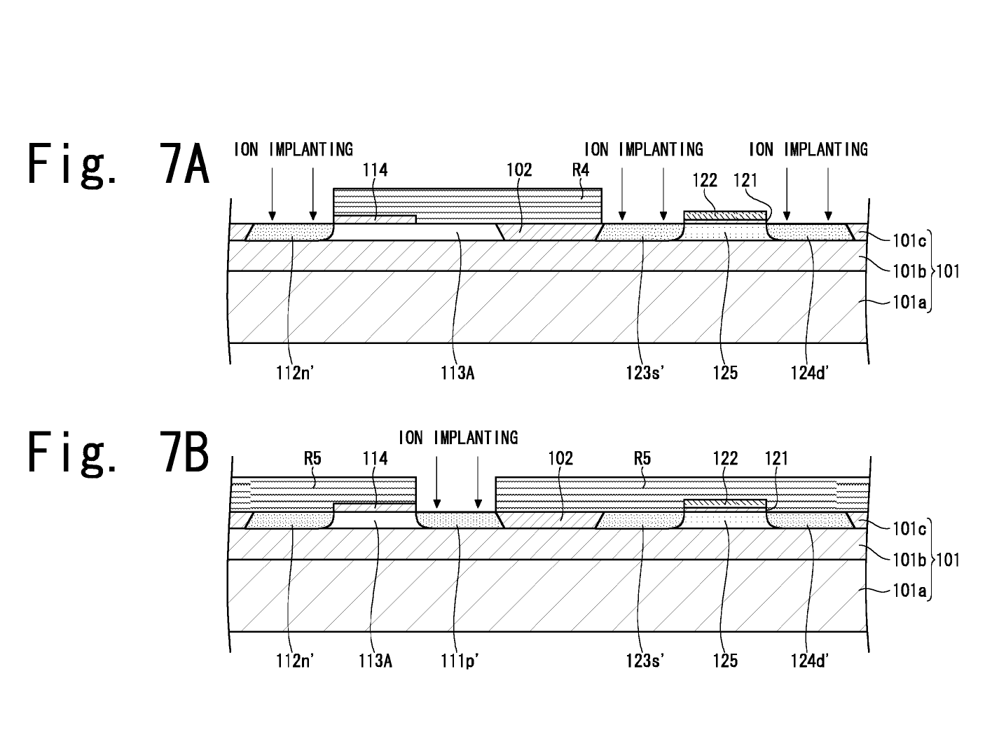

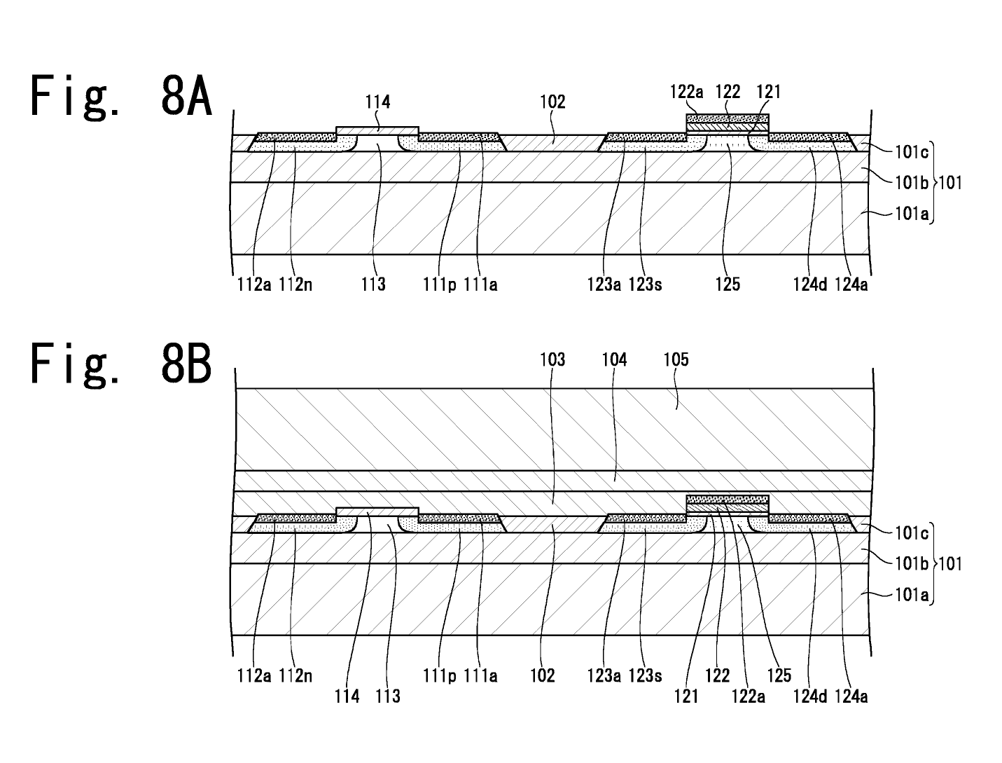

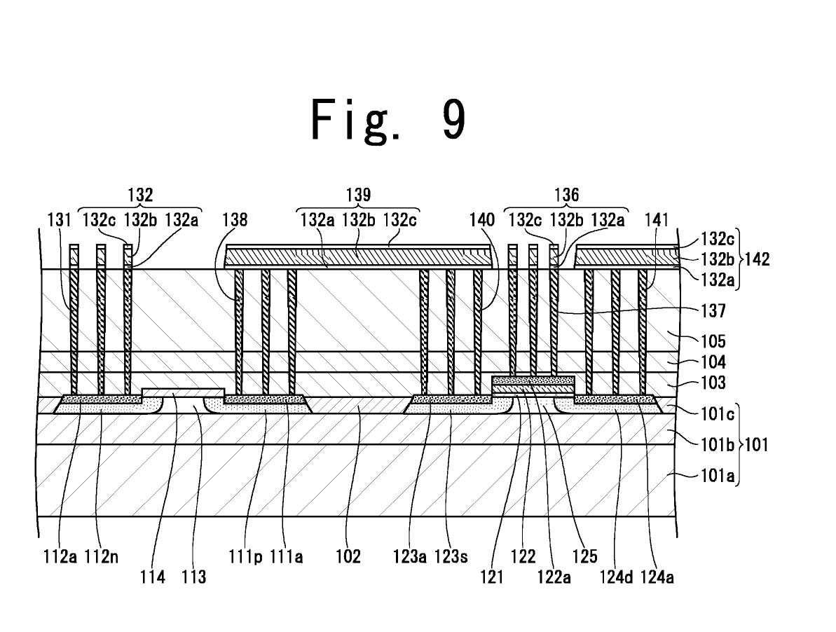

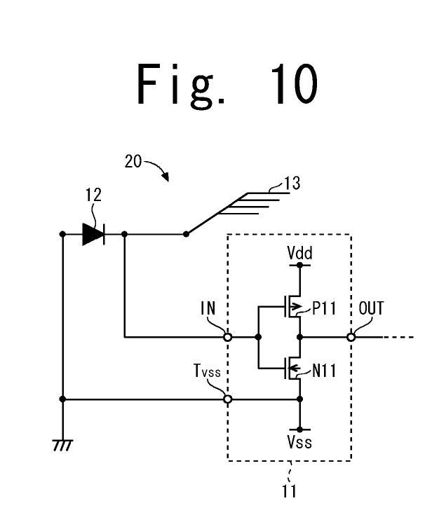

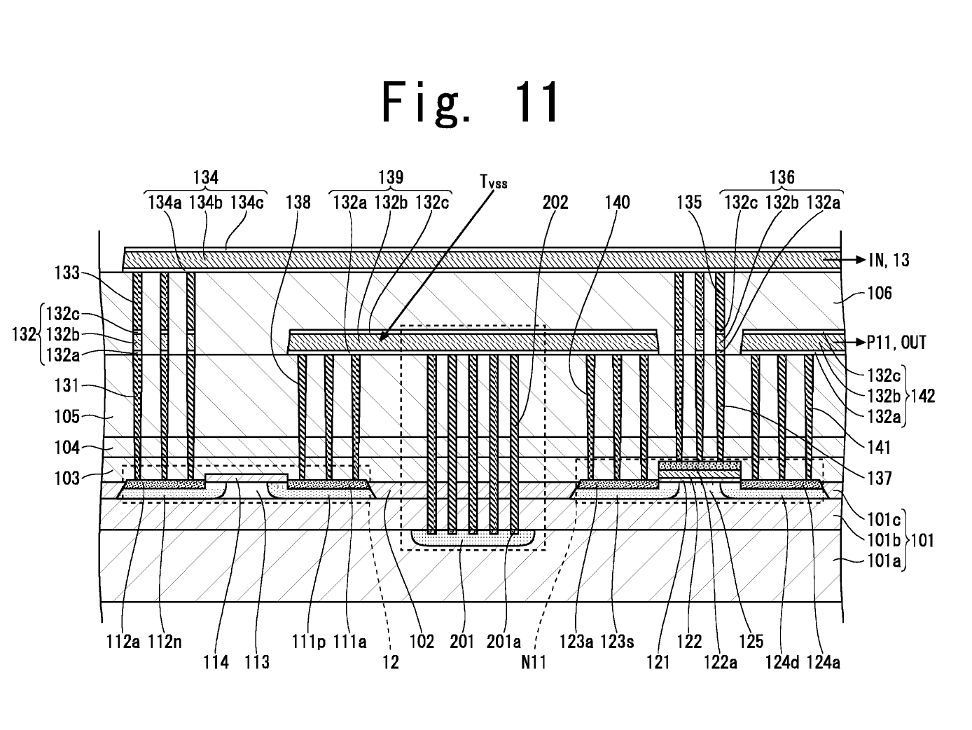

FIG. 4A-4B, 5A-5C, 6A-6B, 7A-7B, 8A-8B, and FIG. 9 are process diagrams showing manufacturing processes in the method of manufacturing the semiconductor device 10 according to this embodiment.

In this manufacturing method, first, an SOI substrate 101 in which an oxide film 101b and a silicon film 101c are sequentially laminated on a silicon substrate 101a is prepared, and by applying an STI (shallow trench isolation) method to this SOI substrate 101, an element separating insulation film 102 as shown in FIG. 4A is formed. By this process, active regions, which are element formation regions, will be formed on the silicon film 101c. Here, the SOI substrate 101 is formed using a p type silicon substrate having a substrate resistance of about 8 to 22 Ω, for instance.

Next, the surface of the SOI substrate will be spin-coated with a resist solution, and then have known exposure and development processes conducted thereon to form a resist pattern R1 on the active region for the protective diode 12. This resist pattern R1 will also be formed on the active region for the PMOS transistor P11. Then, as shown in FIG. 4B, a well region 125A will be formed in the active region where the NMOS transistor N11 is supposed to be formed, by implanting boron fluoride ions, for instance, into the active region for the NMOS transistor N11, to a dose amount of about 1×10¹²/cm², for instance, while using the resist pattern R1 as a mask. At this time, the boron fluoride ions will be accelerated to an energy of about 10 KeV (kilo electron volt), for instance. In this particular process, by being covered by the resist pattern, the active region where the PMOS transistor P11 is supposed to be formed will be prevented from having the boron fluoride ions implanted thereto. In the meantime, in forming a well region in the PMOS transistor P11, resist patterns will be formed on the active regions for the protective diode 12 and the NMOS transistor N11, and while using these resist patterns as masks, phosphorous ions, for instance, will be implanted to the active region for the PMOS transistor P11, to a dose amount of about 1×10¹²/cm², for instance, in order to form the well region in the PMOS transistor P11. The resist patterns used in this process will be removed accordingly, after a low diffusion region or the well region is formed.

Next, by conducting thermal oxidation on the surface of the SOI substrate 101, a silicon oxide film 114A with a thickness of about 400 Å, for instance, will be formed, as shown in FIG. 4C. This silicon oxide film 114A with a thickness of about 400 Å may be formed by setting the heating temperature at 850° C. and the heating time to 5 hours, for instance.

Next, the surface of the silicon oxide film 114A will be spin-coated with a resist solution, and then have known exposure and development processes conducted thereon to form a resist pattern R2 on a region of the protective diode 12 where the protective film 114 is supposed to be formed. Then by using a known etching technique, the silicon oxide film 114A will be patterned, while letting the resist pattern R2 serve as a mask, to form the protective film 114 on the active region for the protective diode 12, as shown in FIG. 5A. Referring to the etching process applied here, it is possible to apply a wet etching process using an etchant such as HF or BHF, etc., for instance.

Next, the resist pattern R2 will be removed, and then, thermal oxidation will be conducted again on the exposed upper surface of the SOI substrate 101 to form a silicon oxide film 121A with a thickness of about 40 Å, for instance, as shown in FIG. 5B. This silicon oxide film 121A with a thickness of about 40 Å may be formed by setting the heating temperature at about 500° C. and the heating time to about 4 hours, for instance.

Next, by using a CVD (chemical vapor deposition) method, for instance, silicon (Si) will be deposited on the silicon oxide film 121A to a thickness of about 2000 Å, while predetermined impurities are being mixed, in order to form a conductive poly-silicon film 122A, as shown in FIG. 5C.

Next, the surface of the poly-silicon film 122A will be spin-coated with a resist solution, and then have known exposure and development processes conducted thereon to form a resist pattern R3 on a region of the NMOS transistor N11 where the gate electrode 122 is supposed to be formed. Then by using a known etching technique, the poly-silicon film 122A will be patterned, while letting the resist pattern R3 serve as a mask, to form the gate electrode 122 on the silicon oxide film 121A in the active region for the NMOS transistor N11, as shown in FIG. 6A. In etching the poly-silicon film 122A, it is preferable that appropriate conditions are applied to secure a sufficient selectivity ratio of the poly-silicon film 122A with respect to the silicon oxide film 121A. Moreover, the etching of the poly-silicon film 122A may be divided into two processes, which are a process for patterning the poly-silicon film 122A (i.e., a main etching process) and a process of over-etching the poly-silicon film 122A (i.e., an over-etching process). As for the main etching process, it is possible to apply a condition in which a mixed gas of Cl₂ gas, HBr gas and O₂ gas is used for the etching gas. As for the over-etching process, it is possible to apply a condition in which a mixed gas of HBr gas, He gas and O₂ gas is used for the etching gas.

Next, the resist pattern R3 will be removed, and then, using a known etching technique, the silicon oxide film 121A will be patterned while letting the gate electrode 122 serve as a mask. By this process, the gate insulation film 121 and the gate electrode 122 are formed on the active region for the NMOS transistor N11, as shown in FIG. 6B. At this time, the protective film 114 formed on the active region for the protective diode 12 may become somewhat thinner. In etching the silicon oxide film 121A, it is preferable that appropriate conditions are applied to secure a sufficient selectivity ratio of the silicon oxide film 121A with respect to the gate electrode 122. Referring to the etching process applied here, it is possible to apply a wet etching process using an etchant such as HF or BHF, etc., for instance.

Next, the surface of the SOI substrate 101 processed in the above-described way will be spin-coated again, and then have known exposure and development processes conducted thereon to form a resist pattern R4 having openings on regions where the N diffusion region 112n in the protective diode 12 is supposed to be formed, and the source 123s and drain 124d in the NMOS transistor N11 are supposed to be formed, respectively. Then, phosphorous ions, for instance, will be implanted to portions of the active regions for the protective diode 12 and for the NMOS transistor N11 exposed at the openings of the resist pattern R4, to a dose amount of about 1×10¹⁵/cm², for instance, while the resist pattern R4 serves as a mask. Thereby, an N diffusion region 112n′ will be formed in the active region for the protective diode 12, and a source 123s′ and a drain 124d′ will be formed on the active region for the NMOS transistor N11, as shown in FIG. 7A. At this time, the phosphorous ions will be accelerated to an energy of about 10 KeV, for instance.

Next, the resist pattern R4 will be removed, and then, the surface of the SOI substrate 101 will be spin-coated again and then have known exposure and development processes conducted thereon to form a resist pattern R5 having an opening on a region where the P diffusion region 111p in the protective diode 12 is supposed to be formed. Then, boron fluoride ions, for instance, will be implanted to a portion of the active region for the protective diode 12 exposed at the opening of the resist pattern R5, to a dose amount of about 1×10¹⁵/cm², for instance, while the resist pattern R5 serves as a mask. Thereby, a P diffusion region 111p′ will be formed in the active region for the protective diode 12, as shown in FIG. 7B. At this time, the boron fluoride ions will be accelerated to an energy of about 10 KeV, for instance. The resist pattern R5 will be removed after the P diffusion region 111p′ is formed in the above-described way.

Next, the SOI substrate will be heat-treated to diffuse the ions implanted in the P diffusion region 111p′, the N diffusion region 112n′, the source 123s′ and the drain 124d′, respectively. Thereby, the P diffusion region 111p and the N diffusion region 112n will be formed in the formation region of the protective diode 12, and the source 123s and the drain 124d will formed in the formation region of the NMOS transistor N11. Referring to the heat treatment applied in this process, it is possible to use lamp-annealing in which the heating temperature is set at 1000° C. and the heating time is set to 10 seconds, for instance.

Next, metal such as cobalt (Co) or titanium (Ti), etc., will be deposited on the SOI substrate and silicified, by which silicide films 111a, 112a, 123a and 124a will be formed on the upper parts of the P diffusion region 111p, the N diffusion region 112n, the source 123s and the drain 124d, respectively, in a self-aligning manner, as shown in FIG. 8A. At this time, since the protective film 114 formed on the active region for the protective diode 12 functions as a mask, no silicide film will be formed in the active region underneath the protective film 114.

Taking the processes as described above, the protective diode 12 and the NMOS transistors N11 will be formed in appropriate active regions in the SOI substrate 101. The PMOS transistor P11 can also be formed in the same way by changing the polarity of ions, etc, to be used.

Next, using a CVD method, for instance, the first passivation 103, the second passivation 104 and the first interlayer insulation film 105 will be formed sequentially on the SOI substrate 101 where the protective diode 12, the NMOS transistor N11 and the PMOS transistor P11 are formed, as shown in FIG. 8B. Here, as mentioned earlier, the first passivation 103 is a silicon oxide film which is about 700 Å thick, the second passivation 104 is a silicon oxide film which is about 1000 Å thick, and the first interlayer insulation film 105 is a silicon oxide film which is about 8000 Å thick, for instance. Moreover, the upper surface of the first interlayer insulation film 105 is planarized using a CMP (chemical and mechanical polishing) method, for instance.

Next, using known photolithography and etching techniques, contact holes will be formed in the first passivation 103, the second passivation 104 and the first interlayer insulation film 105, respectively, and these contact holes will be filled with conductive material such as tungsten (W). Thereby, contact plugs 138 connecting with the silicide film 111a on the P diffusion region 111p, contact plugs 131 connecting with the silicide film 112a on the N diffusion region 112n, contact plugs 137 connecting with the silicide film 122a on the gate electrode 122, contact plugs 140 connecting with the silicide film 123a on the source 123s, and contact plugs 141 connecting with the silicide film 124a on the drain 124d will be formed, respectively. Then, by conducting a CVD method, for instance, a lamination film 132a made of a titanium (Ti) film about 300 Å thick and a titanium nitride (TiN) film about 200 Å thick, for instance, an alloy film 132b made of aluminum (Al) and copper (Cu) to a thickness of about 5000 Å, for instance, and a lamination film 132c made of a titanium (Ti) film about 300 Å thick and a titanium nitride (TiN) film about 200 Å thick, for instance, will be formed sequentially on the first interlayer insulation film 105. Then, by patterning the laminated body made of these films using known photolithography and etching techniques, first upper layer wirings 132 electrically connecting with the contact plugs 131, first upper layer wirings 136 electrically connecting with the contact plugs 137, a first upper layer wiring 139 electrically connecting with the contact plugs 138 and 140, and a first upper layer wiring 142 electrically connecting with the contact plugs 141 will be formed on the first interlayer insulation film 105, as shown in FIG. 9.

Next, by conducting a CVD method, for instance, the second interlayer insulation film 106 with a thickness of about 8000 Å, for instance, will be formed on the first interlayer insulation film 105. In the meantime, the second interlayer insulation film 106 is planarized using a CMP method, for instance.

Next, using known photolithography and etching techniques, contact holes will be formed in the second interlayer insulation film 106, and these contact holes will be filled with conductive material such as tungsten (W) to form contact plugs 133 connecting with the first upper layer wirings 132 and contact plugs 135 connecting with the first upper layer wirings 136, respectively. Then, by conducting a CVD method, for instance, a lamination film 134a made of a titanium (Ti) film about 300 Å thick and a titanium nitride (TiN) film about 200 Å thick, for instance, an alloy film 134b made of aluminum (Al) and copper (Cu) to a thickness of about 5000 Å, for instance, and a lamination film 134c made of a titanium (Ti) film about 300 Å thick and a titanium nitride (TiN) film about 200 Å thick, for instance, will be formed sequentially on the second interlayer insulation film 106. Then, by patterning the laminated body made of these films using known photolithography and etching techniques, a second upper layer wiring 134 electrically connecting with the contact plugs 133 and 135 will be formed on the second interlayer insulation film 106, as shown in FIG. 3.

Taking the processes as described above, it is possible to manufacture the semiconductor device 10 according to the first embodiment of the present invention, as shown in FIG. 3. In this description of the first embodiment of the present invention, although the structure of the PMOS transistor P11 was not described for convenience of explanation, the manufacturing method of the semiconductor device as including the PMOS transistor P11 can be easily assumed based on the above description, and therefore, a detailed description thereof will be omitted here.

As described above, the semiconductor device 10 according to the first embodiment of the present invention uses an SOI substrate 101 which includes a silicon substrate 101a being a support substrate, an oxide film 101b formed on the silicon substrate 101a, and a silicon film 101c formed on the oxide film 101b, and has an input terminal IN (i.e., second upper layer wiring 134) formed on the silicon film 101c, a Vss terminal Tvss (i.e., first upper layer wiring 139) formed on the silicon film 101c, a semiconductor device (e.g., inverter 11) formed on the silicon film 101c and connected with the input terminal IN and the Vss terminal Tvss, and a protective diode 12 formed on the silicon film 101c and connected between the Vss terminal Tvss and the input terminal IN in a forward direction.

Moreover, the method of manufacturing the semiconductor device 10 according to the first embodiment of the present invention includes the steps of preparing an SOI substrate 101 including a silicon substrate 101a being a support substrate, an oxide film 101b formed on the silicon substrate 101a, and a silicon film 101c formed on the oxide film 101b, dividing the silicon film 101c in the SOI substrate 101 into an active region for a protective diode 12 and an active region for a semiconductor element (e.g., NMOS transistor N11) by an element separating insulation film 102, forming a protective diode 12 in the active region for the protective diode 12, the protective diode 12 including a P diffusion region 111p having p type conductivity and an N diffusion region 112n having n type conductivity, forming a transistor (e.g., NMOS transistor N11) in the active region for the semiconductor element, the transistor including a gate insulation film 121, a gate electrode 122 and a pair of source 123s and drain 124d, forming a wiring (i.e., first wiring) electrically connecting between the P diffusion region 111p of the protective diode and the source 123s of the transistor, and forming a wiring (i.e., second wiring) electrically connecting between the N diffusion region 112n of the protective diode and the gate electrode 122 of the transistor.

For instance, when the semiconductor element includes a transistor (i.e., NMOS transistor N11 in this embodiment) having a source and drain formed in the silicon film 101c, the source, drain and gate will be in an electrically floating state with respect to the silicon substrate 101a being a support substrate. Considering such a situation, in this embodiment of the present invention, the protective diode 12 is adapted to be connected in between the source and gate in a forward direction. By this arrangement, it is possible to eliminate a possible potential difference between the source and gate. As a result, in this embodiment, it is possible to prevent a possible plasma current that could occur during the manufacturing process from intensively flowing into the gate, in particular, and thereby it is possible to prevent the semiconductor device 10 from being damaged.

Moreover, the protective diode 12 in this embodiment does not have any conductive film on a region in between the P diffusion region 111p and the N diffusion region 112n. Therefore, it is possible to prevent a withstand voltage of the protective diode 12 from becoming higher, prevent the discharge efficiency with respect to surge current such as plasma current, etc., from decreasing, and prevent the semiconductor device 10 from having less control over plasma damage.

### Second Embodiment

Now, a second embodiment of the present invention will be described in detail with reference to the drawings. In the following description, the same reference numbers will be used for the same structural elements as those in the first embodiment, and redundant explanations thereof will be omitted. Moreover, the structure which will not be mentioned in particular is the same as that in the first embodiment. In this embodiment, as with the first embodiment, a case in which a semiconductor element to be formed in an SOI substrate is an inverter will be described.

Structure

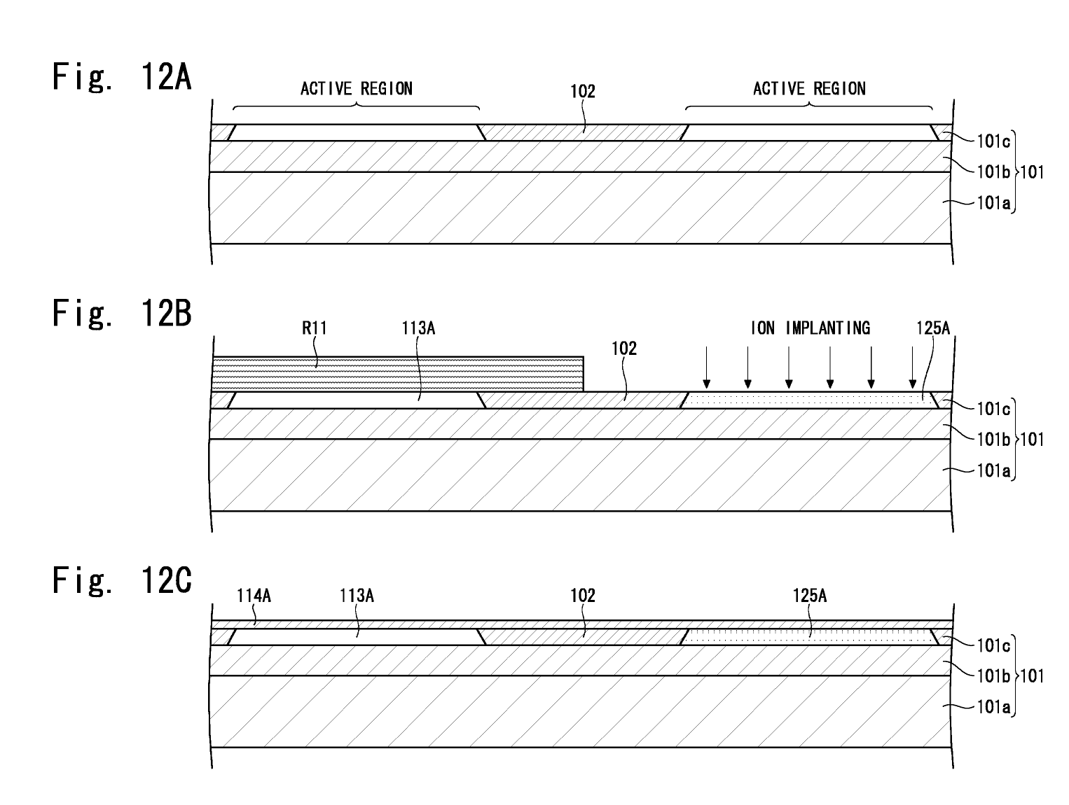

FIG. 10 is a circuit diagram showing the structure of a semiconductor device 20 according to the second embodiment of the present invention. As shown in FIG. 20, the semiconductor device 20 has the same structure as the semiconductor device 10 according to the first embodiment of the present invention (q.v., FIG. 2), except that in the semiconductor device 20, a wiring connecting the anode of the protective diode 12 and the Vss terminal Tvss is connected to a substrate. Since the rest of the structure is the same as the semiconductor device 10, a detailed description thereof will be omitted here.

Because the anode of the protective diode 12 and the Vss terminal Tvss are arranged to be connected to the substrate, even if a current greater than a junction withstand voltage of the protective diode 12, for instance, is inputted between the Vss terminal Tvss and the input terminal IN, it will become possible to let such current flow toward the silicon substrate 101a in the SOI substrate 101. As a result, it will become possible to prevent the semiconductor element formed in the SOI substrate from becoming damaged by plasma current more effectively. Here, the junction withstand voltage is defined as a voltage at which the protective diode 12 will break down. In the meantime, the cathode of the protective diode 12 and the gate of the inverter 11 are electrically connected to the metal wiring 13. Sectional Structure of Semiconductor Device

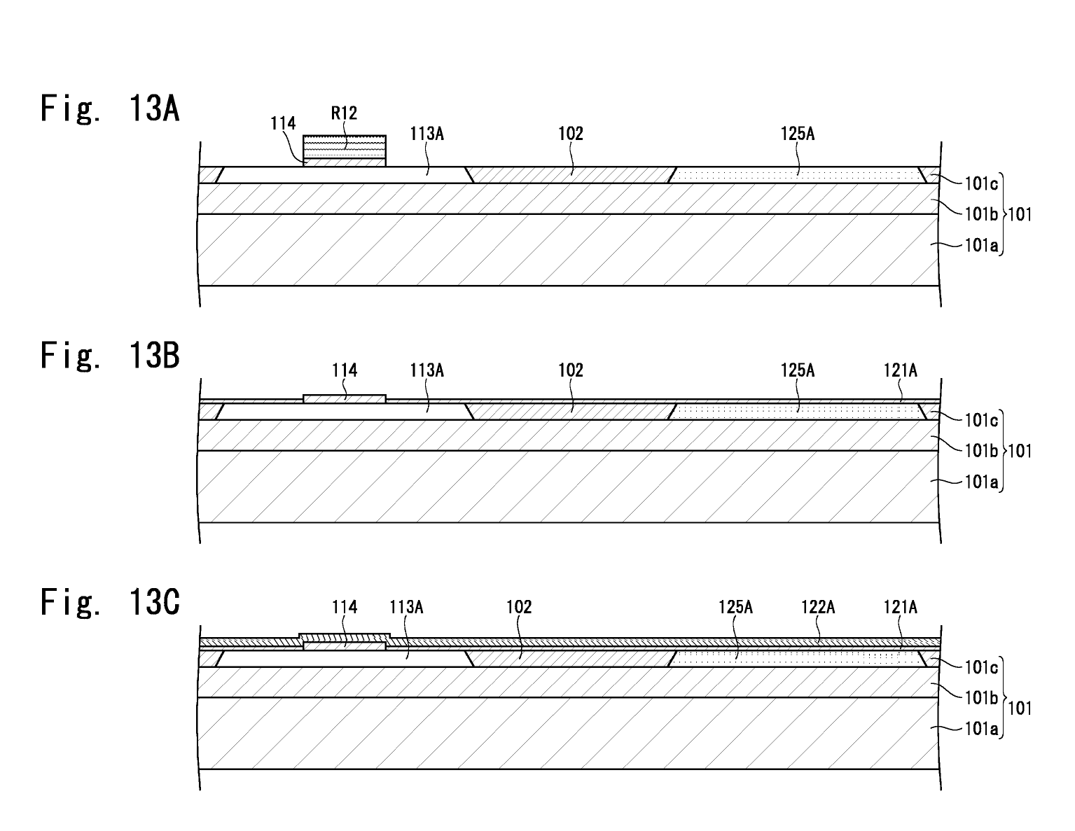

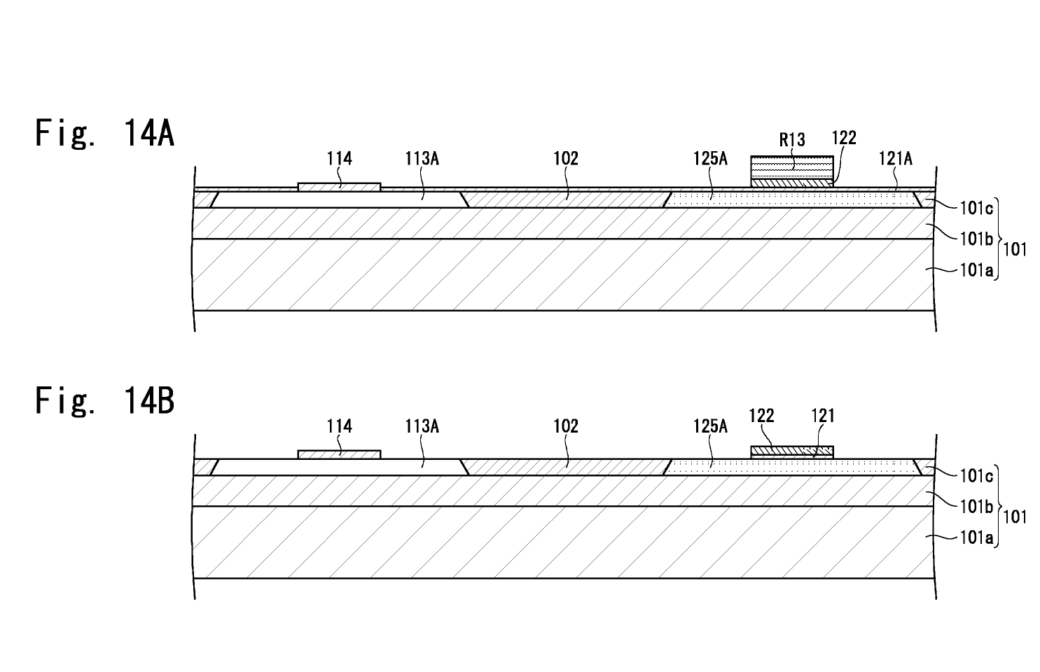

Now, the layer structure of the semiconductor device 20 according to the second embodiment of the present invention will be described in detail with reference to a drawing. FIG. 11 is a sectional view showing the layer structure of the semiconductor device 20. In FIG. 11, a section of the semiconductor device 20 cut along a surface perpendicular to the upper surface of the SOI substrate 101 is shown. Moreover, in FIG. 11, for convenience of explanation, the structure of the PMOS transistor P11 is omitted.

As shown in FIG. 11, the semiconductor device 20 has the same structure as the semiconductor device 10 according to the first embodiment of the present invention (q.v., FIG. 3), and in addition to that, it has the first upper layer wiring 139, which connects between the P diffusion region 111p in the protective diode 12 and the source 123s in the NMOS transistor N11, connected to a substrate contact 201 formed in the SOI substrate 101 via contact plugs 202. Here, the substrate contact 201 is a component serving to gain electrical connection with the silicon substrate 101a in the SOI substrate 101. In addition, the upper part of the substrate contact 201 has a silicide film 201a formed thereon, by which it is made to have low resistance.

In this structure, the substrate contact 201 is formed by having p type impurities (e.g., boron B) implanted into the silicon substrate 101a in the SOI substrate 101 to a dose amount of about 1×10¹⁵/cm², for instance. In forming this substrate contact 201, the ions may be implanted into the silicon substrate 101a through contact holes penetrating through the element separation insulation film 102 and the oxide film 101b in the SOI substrate, and then diffused.

Since the rest of the structure of the semiconductor device 20 is the same as the semiconductor device 10 (q.v., 3), a detailed description thereof will be omitted here.

Method of Manufacturing the Semiconductor Device

Now, a method of manufacturing the semiconductor device 20 according to the second embodiment of the present invention will be described in detail with reference to the drawings. The following description will be based on the sectional structure of the semiconductor device 20 as shown in FIG. 11, the semiconductor device 20 being cut along a surface perpendicular to the upper surface of the SOI substrate 101. Moreover, in the following, the manufacturing method will be described focusing on the protective diode 12 and the NMOS transistor N11.

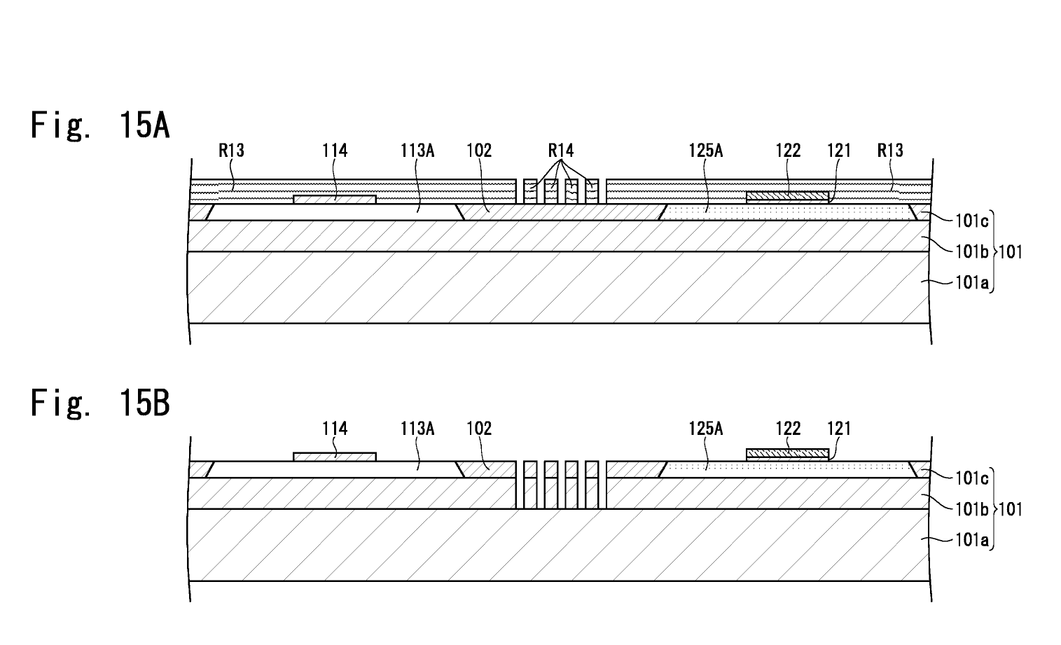

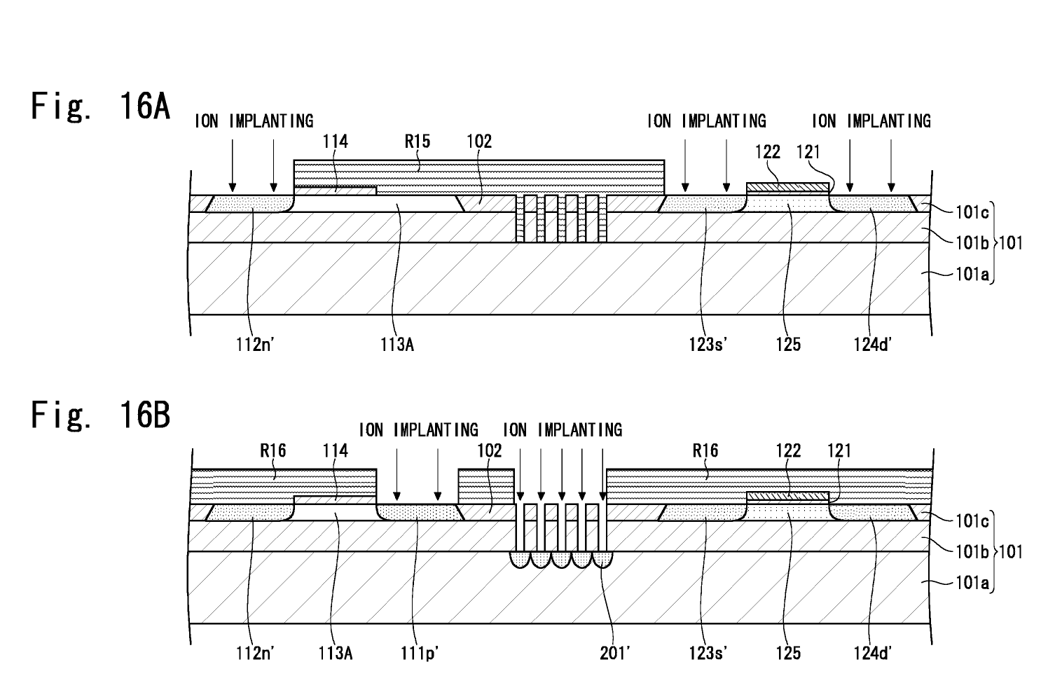

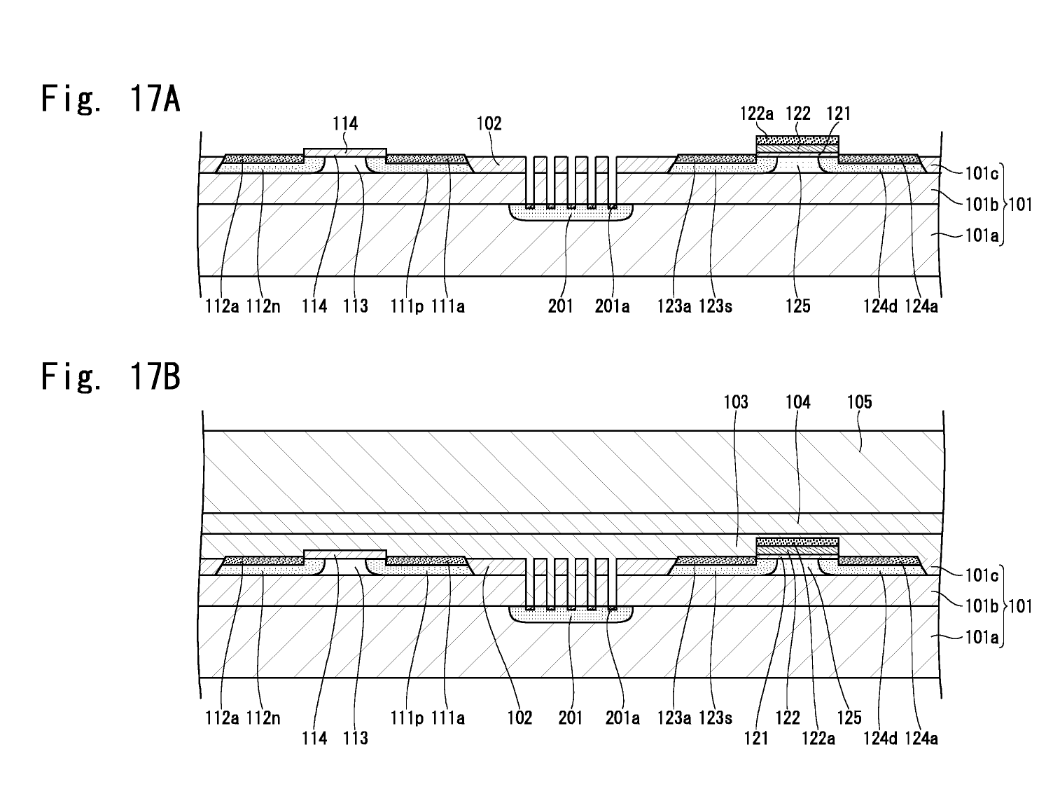

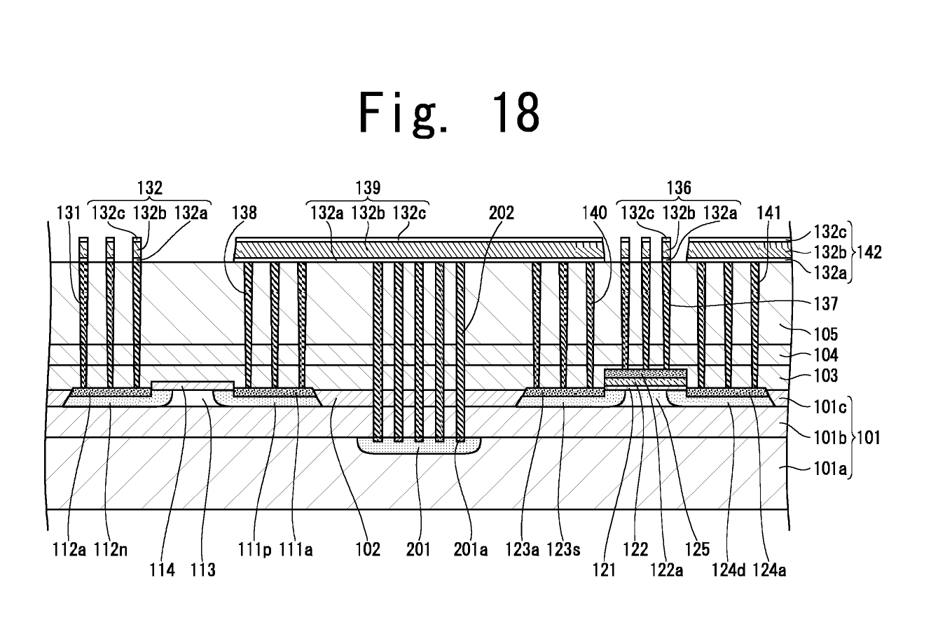

FIG. 12A-12C, 13A-13C, 14A-14B, 15A-15B, 16A-16B, 17A-17B, and FIG. 18 are process diagrams showing manufacturing processes in the method of manufacturing the semiconductor device 20 according to this embodiment.

In this manufacturing method, first, an SOI substrate 101 in which an oxide film 101b and a silicon film 101c are sequentially laminated on a silicon substrate 101a is prepared, and by applying an STI (shallow trench isolation) method to this SOI substrate 101, an element separating insulation film 102 as shown in FIG. 12A will be formed. By this process, active regions, which are element formation regions, will be formed on the silicon film 101c. Here, as with the case of the first embodiment, the SOI substrate 101 is formed using a p type silicon substrate having a substrate resistance of about 8 to 22 Ω, for instance.

Next, the surface of the SOI substrate will be spin-coated with a resist solution, and then have known exposure and development processes conducted thereon to form a resist pattern R11 on the active region for the protective diode 12. This resist pattern R11 will also be formed on the active region for the PMOS transistor P11. Then, as shown in FIG. 12B, a well region 125A will be formed in the active region where the NMOS transistor N11 is supposed to be formed, by implanting boron fluoride ions, for instance, into the active region for the NMOS transistor N11, to a dose amount of about 1×10¹²/cm², for instance, while using the resist pattern R11 as a mask. At this time, the boron fluoride ions will be accelerated to an energy of about 10 KeV (kilo electron volt), for instance. In this particular process, by being covered by the resist pattern, the active region where the PMOS transistor P11 is supposed to be formed will be prevented from having the boron fluoride ions implanted thereto. In the meantime, in forming a well region in the PMOS transistor P11, resist patterns will be formed on the active regions for the protective diode 12 and the NMOS transistor N11, and while using these resist patterns as masks, phosphorous ions, for instance, will be implanted into the active region for the PMOS transistor P11, to a dose amount of about 1×10¹²/cm², for instance, in order to form the well region in the PMOS transistor P11. The resist patterns used in this process will be removed appropriately after a low diffusion region or the well region is formed.

Next, by conducting thermal oxidation on the surface of the SOI substrate 101, a silicon oxide film 114A with a thickness of about 400 Å, for instance, will be formed, as shown in FIG. 12C. This silicon oxide film 114A with a thickness of about 400 Å may be formed by setting a heating temperature at 850° C. and a heating time to 5 hours, for instance.

Next, the surface of the silicon oxide film 114A will be spin-coated with a resist solution, and then have known exposure and development processes conducted thereon to form a resist pattern R12 on a region of the protective diode 12 where the protective film 114 is supposed to be formed. Then by using a known etching technique, the silicon oxide film 114A will be patterned, while letting the resist pattern R12 serve as a mask, to form the protective film 114 on the active region for the protective diode 12, as shown in FIG. 13A. Referring to the etching process applied here, it is possible to apply a wet etching process using an etchant such as HF or BHF, etc., for instance.

Next, the resist pattern R12 will be removed, and then, thermal oxidation will be conducted again on the exposed upper surface of the SOI substrate 101 to form a silicon oxide film 121A with a thickness of about 40 Å, for instance, as shown in FIG. 13B. This silicon oxide film 121A with a thickness of about 40 Å may be formed by setting a heating temperature at about 500° C. and a heating time to about 4 hours, for instance.

Next, by using a CVD method, for instance, silicon (Si) will be deposited on the silicon oxide film 121A to a thickness of about 2000 Å, while predetermined impurities are being mixed, in order to form a conductive poly-silicon film 122A, as shown in FIG. 13C.

Next, the surface of the poly-silicon film 122A will be spin-coated with a resist solution, and then have known exposure and development processes conducted thereon to form a resist pattern R13 on a region of the NMOS transistor N11 where the gate electrode 122 is supposed to be formed. Then, by using a known etching technique, the poly-silicon film 122A will be patterned, while letting the resist pattern R3 serve as a mask, to form the gate electrode 122 on the silicon oxide film 121A in the active region for the NMOS transistor N11, as shown in FIG. 14A. In etching the poly-silicon film 122A, it is preferable that appropriate conditions are applied to secure a sufficient selectivity ratio of the poly-silicon film 122A with respect to the silicon oxide film 121A. Moreover, as in the case of the first embodiment, the etching of the poly-silicon film 122A may be divided into two processes, which are a main etching process and an over-etching process. As for the main etching process, it is possible to apply a condition in which a mixed gas of Cl₂ gas, HBr gas and O₂ gas is used for the etching gas. As for the over-etching process, it is possible to apply a condition in which a mixed gas of HBr gas, He gas and O₂ gas is used for the etching gas.

Next, the resist pattern R13 will be removed, and then, using a known etching technique, the silicon oxide film 121A will be patterned while letting the gate electrode 122 serve as a mask. By this process, the gate insulation film 121 and the gate electrode 122 are formed on the active region for the NMOS transistor N11, as shown in FIG. 14B. At this time, the protective film 114 formed on the active region for the protective diode 12 may become somewhat thinner. In etching the silicon oxide film 121A, it is preferable that appropriate conditions are applied to secure a sufficient selectivity ratio of the silicon oxide film 121A with respect to the gate electrode 122. Referring to the etching process applied here, it is possible to apply a wet etching process using an etchant such as HF or BHF, etc., for instance. The processes as mentioned up to this point are the same as those in the first embodiment (q.v., FIG. 4A to FIG. 6B).

Next, the surface of the SOI substrate 101 processed in the above-described way will be spin-coated again, and then have known exposure and development processes conducted thereon to form a resist pattern R14 having openings on portions of the element separation insulation film 102 that defines the field regions, as shown in FIG. 15A. Here, the openings in the resist pattern R14 will be formed at positions that are sufficiently separated from each active region.

Next, the portions of the element separation insulation film 102 exposed at the openings of the resist pattern R14 and corresponding portions of the oxide film 101b in the SOI substrate will be etched sequentially using a known etching technique, to form openings which penetrate through these films, as shown in FIG. 15B.

Next, the resist pattern R14 will be removed, and then, the surface of the SOI substrate 101, having been processed as described above, will be spin-coated again, and then have known exposure and development processes conducted thereon to form a resist pattern R15 having openings on a region of the protective diode 12 where the N diffusion region 112n is supposed to be formed and on regions of the NMOS transistor N11 where the source 123s and drain 124d are supposed to be formed, respectively. Then, phosphorous ions, for instance, will be implanted to portions of the active regions for the protective diode 12 and for the NMOS transistor N11 exposed at the openings of the resist pattern R15, to a dose amount of about 1×10¹⁵/cm², for instance, while the resist pattern R15 serves as a mask. Thereby, an N diffusion region 112n′ will be formed in the active region for the protective diode 12, and a source 123s′ and a drain 124d′ will be formed on the active region for the NMOS transistor N11, as shown in FIG. 16A. At this time, the phosphorous ions will be accelerated to an energy of about 10 KeV, for instance.

Next, the resist pattern R15 will be removed, and then, the surface of the SOI substrate 101 will be spin-coated again, and then have known exposure and development processes conducted thereon to form a resist pattern R16 having openings on a region of the protective diode 12 where the P diffusion region 111p is supposed to be formed and on the openings formed in the element separation insulation film 102 and in the oxide film 101b in the SOI substrate 101. Then, boron fluoride ions, for instance, will be implanted to a portion of the active region for the protective diode 12 and portions of the silicon substrate 101a in the SOI substrate which are exposed at the openings of the resist pattern 16, to a dose amount of about 1×10¹⁵/cm², for instance, while the resist pattern R16 serves as a mask. Thereby, a P diffusion region 111p′ will be formed in the active region for the protective diode 12, and a P diffusion region 201′, which is supposed to turn into the substrate contact 201, will be formed in the silicon substrate 101a in the SOI substrate 101, as shown in FIG. 16B. At this time, the boron fluoride ions will be accelerated to an energy of about 10 KeV, for instance. The resist pattern R16 will be removed after the P diffusion regions 111p′ and 201′ are formed in the above-described way.

Next, the SOI substrate will be heat-treated to diffuse the ions implanted to the P diffusion region 111p′, the N diffusion region 112n′, the source 123s′, the drain 124d′, and the P diffusion region 201′, respectively. Thereby, the P diffusion region 111p and the N diffusion region 112n will be formed in the formation region of the protective diode 12, the source 123s and the drain 124d will be formed in the formation region of the NMOS transistor N11, and the substrate contact 201 will be formed in the silicon substrate 101a. Referring to the heat treatment applied in this process, it is possible to use lamp-annealing, in which the heating temperature is set at 1000° C. and the heating time is set to 10 seconds, for instance.

Next, metal such as cobalt (Co) or titanium (Ti), etc., will be deposited on the SOI substrate and silicified, by which silicide films 111a, 112a, 123a, 124a and 201a will be formed on the upper parts of the P diffusion region 111p, the N diffusion region 112n, the source 123s, the drain 124d and the substrate contact 201, respectively, in a self-aligning manner, as shown in FIG. 17A. At this time, since the protective film 114 formed on the active region for the protective diode 12 functions as a mask, no silicide film will be formed in the active region underneath the protective film 114.

Taking the processes as described above, the protective diode 12 and the NMOS transistors N11 will be formed in appropriate active regions in the SOI substrate 101. The PMOS transistor P11 can also be formed in the same way by changing the polarity of ions, etc., to be used.

Next, using a CVD method, for instance, the first passivation 103, the second passivation 104 and the first interlayer insulation film 105 will be formed sequentially on the SOI substrate 101, as shown in FIG. 17B. Here, the first passivation 103 will be formed while plugging up the openings formed in the element separation insulation film 102 and in the oxide film 101b in the SOI substrate 101. As mentioned earlier, the first passivation 103 is a silicon oxide film which is about 700 Å thick, the second passivation 104 is a silicon oxide film which is about 1000 Å thick, and the first interlayer insulation film 105 is a silicon oxide film which is about 8000 Å thick, for instance. Moreover, the upper surface of the first interlayer insulation film 105 is planarized using a CMP (chemical and mechanical polishing) method, for instance.

Next, using known photolithography and etching techniques, contact holes will be formed in the first passivation 103, the second passivation 104 and the first interlayer insulation film 105, exposing the silicide film 111a on the P diffusion region 111p, the silicide film 112a on the N diffusion region 112n, the silicide film 122a on the gate electrode 122, the silicide film 123a on the source 123s and the silicide film 124a on the drain 124d. At the same time, contact holes will be formed in the oxide film 101b in the SOI substrate, the element separation insulation film 102, the first passivation 103, the second passivation 104 and the first interlayer insulation film 105, exposing the silicide film 201a on the substrate contact 201. Then, by having these contact holes filled with conductive material such as tungsten (W), contact plugs 138 connecting with the silicide film 111a on the P diffusion region 111p, contact plugs 131 connecting with the silicide film 112a on the N diffusion region 112n, contact plugs 137 connecting with the silicide film 122a on the gate electrode 122, contact plugs 140 connecting with the silicide film 123a on the source 123s, contact plugs 141 connecting with the silicide film 124a on the drain 124d, and contact plugs 202 connecting with the silicide film 201a on the substrate contact 201 will be formed, respectively. Then, by conducting a CVD method, for instance, a lamination film 132a made of a titanium (Ti) film about 300 Å thick and a titanium nitride (TiN) film about 200 Å thick, for instance, an alloy film 132b made of aluminum (Al) and copper (Cu) to a thickness of about 5000 Å, for instance, and a lamination film 132c made of a titanium (Ti) film about 300 Å thick and a titanium nitride (TiN) film about 200 Å thick, for instance, will be formed sequentially on the first interlayer insulation film 105. Then, by patterning the laminated body made of these films using known photolithography and etching techniques, first upper layer wirings 132 electrically connecting with the contact plugs 131, first upper layer wirings 136 electrically connecting with the contact plugs 137, a first upper layer wiring 139 electrically connecting with the contact plugs 138, 140 and 202, and a first upper layer wiring 142 electrically connecting with the contact plugs 141 will be formed on the first interlayer insulation film 105, as shown in FIG. 18.

Next, by conducting a CVD method, for instance, the second interlayer insulation film 106 with a thickness of about 8000 Å, for instance, will be formed on the first interlayer insulation film 105. In the meantime, the second interlayer insulation film 106 is planarized using a CMP method, for instance.

Next, using known photolithography and etching techniques, contact holes will be formed in the second interlayer insulation film 106, and these contact holes will be filled with conductive material such as tungsten (W) to form contact plugs 133 connecting with the first upper layer wirings 132 and contact plugs 135 connecting with the first upper layer wirings 136, respectively. Then, by conducting a CVD method, for instance, a lamination film 134a made of a titanium (Ti) film about 300 Å thick and a titanium nitride (TiN) film about 200 Å thick, for instance, an alloy film 134b made of aluminum (Al) and copper (Cu) to a thickness of about 5000 Å, for instance, and a lamination film 134c made of a titanium (Ti) film about 300 Å thick and a titanium nitride (TiN) film about 200 Å thick, for instance, will be formed sequentially on the second interlayer insulation film 106. Then, by patterning the laminated body made of these films using known photolithography and etching techniques, a second upper layer wiring 134 electrically connecting with the contact plugs 133 and 135 will be formed on the second interlayer insulation film 106, as shown in FIG. 11.

Taking the processes as described above, it is possible to manufacture the semiconductor device 20 according to the second embodiment of the present invention, as shown in FIG. 11. In this description of the second embodiment of the present invention, although the structure of the PMOS transistor P11 has not been described for the convenience of explanation, the manufacturing method of the semiconductor device as including the PMOS transistor P11 can be easily assumed based on the above description, and therefore, a detailed description thereof will be omitted here.

As described above, the semiconductor device 20 according to the second embodiment of the present invention uses an SOI substrate 101 which includes a silicon substrate 101a that is a support substrate, an oxide film 101b formed on the silicon substrate 101a, and a silicon film 101c formed on the oxide film 101b, and has an input terminal IN (i.e., second upper layer wiring 134) formed on the silicon film 101c, a Vss terminal Tvss (i.e., first upper layer wiring 139) formed on the silicon film 101c, a semiconductor device (e.g., inverter 11) formed on the silicon film 101c and connected with the input terminal IN and the Vss terminal Tvss, and a protective diode 12 formed on the silicon film 101c and connected between the Vss terminal Tvss and the input terminal IN in a forward direction, the Vss terminal Tvss connecting to the silicon substrate 101a.

Moreover, the method of manufacturing the semiconductor device 20 according to the second embodiment of the present invention includes the steps of preparing an SOI substrate 101 including a silicon substrate 101a that is a support substrate, an oxide film 101b formed on the silicon substrate 101a, and a silicon film 101c formed on the oxide film 101b, dividing the silicon film 101c in the SOI substrate 101 into an active region for a protective diode 12 and an active region for a semiconductor element (e.g., NMOS transistor N11) by an element separating insulation film 102, forming a protective diode 12 in the active region for the protective diode 12, the protective diode 12 including a P diffusion region 111p having p type conductivity and an N diffusion region 112n having n type conductivity, forming a transistor (e.g., NMOS transistor N11) in the active region for the semiconductor element, the transistor including a gate insulation film 121, a gate electrode 122 and a pair of source 123s and drain 124d, forming a wiring (i.e., first wiring) electrically connecting between the P diffusion region 111p of the protective diode and the source 123s of the transistor, forming a wiring (i.e., second wiring) electrically connecting between the N diffusion region 112n of the protective diode and the gate electrode 122 of the transistor, and connecting the P diffusion region 111p in the protective diode 12 to the silicon substrate 101a.

By having such structure, even if a current greater than a junction withstand voltage of the protective diode 12, for instance, is inputted between the Vss terminal Tvss and the input terminal IN, it will become possible to let such current flow toward the silicon substrate 101a in the SOI substrate 101. As a result, it will become possible to prevent the semiconductor element formed in the SOI substrate from becoming damaged by plasma current more effectively. Since the other effects are the same as those in the first embodiment of the present invention, they will not be mentioned here again.

In the first and second embodiments of the present invention, the impurity density of the low diffusion region 113 (q.v., FIG. 3 or FIG. 11) in the protective diode 12 is the same as the substrate density of the SOI substrate 101. However, the present invention is not limited to such condition, and it is also possible to change, where appropriate, the kind of impurities to be applied, the impurity density and acceleration energy at the time of impurity implantation, and achieve a junction withstand voltage of the protective diode 12 suited to the manufacturing process of the semiconductor device 10/20.

For instance, if the second upper layer wiring 134 (corresponding to the metal wiring 13) is a seven-layer structure, there will be a greater number of processes requiring use of plasma as compared to the cases applying a three-layer structure as in the above-described embodiments. Therefore, as the number of layers in the layer structure of the second upper layer wiring 134 increases, there will be a greater number of inputs of plasma current to the second upper layer wiring 134 (i.e., metal wiring 13), which will result in magnifying damage accumulation in the protective diode 12, etc. Considering such a problem, by setting a dose amount of the low diffusion region 113 to be about 1×10¹³/cm², for instance, it will become possible to raise a junction withstand voltage between the P diffusion region 111p and the N diffusion region 112n in the protective diode 12. This means that the impurity density of the low diffusion region 113 is supposed to be set appropriately depending on the layer structure of the metal wiring 13. Thereby, it is possible to raise the breakdown voltage of the protective diode 12. As a result, it is possible to achieve a semiconductor device having higher resistance characteristic against plasma current that could occur during a manufacturing process thereof.

While the preferred embodiments of the invention have been described using specific terms, such description is for illustrative purposes only, and it is to be understood that changes and variations may be made without departing from the spirit or the scope of the following claims.

This application claims priority to Japanese Patent Application No. 2005-294243. The entire disclosures of Japanese Patent Application No. 2005-294243 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

What is claimed is:

1. A semiconductor device comprising:
a substrate;
a first oxide film lying on the substrate;
a thin semiconductor film lying on the first oxide film;
a first terminal formed on the semiconductor film;
a second terminal formed on the semiconductor film;
a semiconductor element formed on the semiconductor film and electrically connected between the first and second terminals; and
a protective diode formed on the semiconductor film and electrically connected in between the second and first terminal in a forward direction.

2. The semiconductor device according to claim 1, wherein
the protective diode is a lateral type diode.

3. The semiconductor device according to claim 1, wherein
the semiconductor element is a transistor,
the first terminal is electrically connected with a gate of the transistor, and
the second terminal is electrically connected with a source of the transistor.

4. The semiconductor device according to claim 1, further comprising:
a signal line formed on the semiconductor film; and
a power supply line formed on the semiconductor film,
wherein the first terminal is electrically connected with the signal line, and
the second terminal is electrically connected with the power supply line.

5. The semiconductor device according to claim 1, wherein
the protective diode comprises
a first doped region having a p type conductivity formed on the semiconductor film,
a second doped region having a n type conductivity formed on the semiconductor film, and
a third doped region formed between the first and second doped regions,
wherein a p or n type impurity concentration of the third doped region is lower than that of the first or second doped region.

6. The semiconductor device according to claim 5, further comprising:
a first silicide film formed on the first doped region;
a second silicide film formed on the second doped region; and
a second oxide film formed at least on the third doped region.

7. The semiconductor device according to claim 1, wherein
the second terminal is electrically connected with the substrate.

8. The semiconductor device according to claim 7, wherein
the substrate comprises a fourth doped region doped with p or n type impurities,
wherein the second terminal is electrically connected with the fourth doped region.

9. The semiconductor device according to claim 5, further comprising:
a metal layer formed over the semiconductor element,
wherein the impurity concentration of the third doped region is set based on the structure of the metal layer.
